(19) United States
(12) Patent Application Publication
(10) Pub. No.: US 2009/0311862 A1
(43) Pub. Date: Dec. 17, 2009

(54) Method for manufacturing a semiconductor wafer

(75) Inventors: Tomoaki Tajiri, Omura-Shi (JP); Daisuke Maruoka, Nagasaki (JP)

Correspondence Address: EDWARDS ANGELL PALMER & DODGE LLP, P.O. BOX 55874, BOSTON, MA, 02205, US

(73) Assignee: SUMCO TECHXIV CORPORATION, Nagasaki (JP)

(21) Appl. No.: 12/456,355

(22) Filed: Jun. 15, 2009

(30) Foreign Application Priority Data
Jun. 17, 2008 (JP) 2008-158269

(51) Int. Cl. H01L 21/302

(52) U.S. Cl. 438/691; 257/E21.214

(57) ABSTRACT

By removing residual mechanical stress generated during processing, wafers can be manufactured while suppressing deformation and cracking of the wafer even if the wafer is a large-diameter wafer. A method for manufacturing a wafer, includes: a slicing step (S10) for slicing an ingot to obtain a wafer; a double-sided simultaneous grinding step (S20) for roughly grinding the cut surfaces of each wafer; a chamfering step (S22) for chamfering the edge portion of the wafer; a double-sided simultaneous processing step for simultaneously processing both faces of the wafer so as to remove residual mechanical stress generated on the both faces thereof due to the slicing step and the double-sided grinding step; a single-sided finishing step for separately performing finishing processing on at least one face of the wafer; and a cleaning step for cleaning the wafer.

The present application claims the benefit of priority from Japanese Patent Application No. 2008-158269 filed on Jun. 17, 2008, the entire content of which is hereby incorporated by reference.

### BACKGROUND OF THE INVENTION

1. Field of the Invention

The present invention relates to a method for manufacturing a semiconductor wafer (hereinafter, also referred to as “wafer”).

2. Related Art

FIG. 7 through FIG. 10 are flowcharts which show a conventional and general method for manufacturing a wafer. FIG. 11 is a schematic side view which shows a wafer having residual mechanical stress generated during processing due to a slicing step and a rough finishing step. FIG. 12 is a schematic side view which shows a warped wafer.

Referring to FIG. 7, description will be made regarding an example of a general method for manufacturing a wafer to produce a semiconductor device. First, in the slicing step (Step S10), a single-crystal semiconductor ingot manufactured using a Czochralski method (CZ method), a floating zone method (FZ method), or the like is sliced into disc-shaped thin wafers using a disc-shaped inner diameter blade or the like, as shown in FIG. 7.

Then, in Step S20, both the front face and the back face (hereinafter, also referred to as “both faces”) of each wafer are ground at the same time using grindstones (not shown) arranged on the front-face side and the back-face side of the wafer. Such a step in which both faces are ground at the same time (rough finishing step) is hereinafter, also referred to as “double-sided simultaneous grinding”.

Here, the wafer sliced in the slicing step (Step S10) has poor flatness and large surface roughness on both faces thereof, leading to waviness of the wafer. Accordingly, in the double-sided simultaneous grinding step (Step S20), rough grinding is performed on both faces of the wafer, thereby removing the waviness of the wafer.

Subsequently, in order to protect the edge of the wafer from chipping, the edge portion is chamfered in a chamfering step (Step S22).

After the chamfering step (Step S22), double-sided polishing (single-sided finishing step) is performed (Step S50), in which both faces of the wafer are separately subjected to finishing polishing one face after the other. Such a double-sided polishing step realizes extremely high flatness of the wafer. It should be noted that, in the drawings, a step in which both faces of a wafer are separately processed, one face after the other, is indicated by “one face after the other” for convenience of description.

Last, in a cleaning step (Step S60), cleaning is performed so as to remove residual abrasive grains, impurities, etc., due to the double-sided polishing step (Step S50), etc. This provides a wafer with desired specifications.

In some cases, the method for manufacturing the wafer can include a different step from those shown in FIG. 7, according to the requested specifications (performance) of the wafer or the like. Referring to FIG. 8 through FIG. 10, description will be made below regarding another method for manufacturing the wafer.

That is to say, in some cases, instead of the double-sided simultaneous grinding processing in Step S20 shown in FIG. 7, a lapping step is performed as a rough finishing step, as shown in Step S24 in FIG. 8. In the lapping step, the wafer is planed so as to improve the flatness thereof by removing the waviness of the wafer imparted by the slicing step (Step S10). The other steps are the same as those shown in FIG. 7 except for Step S24 shown in FIG. 8. Accordingly, description thereof will be omitted.

In the double-sided polishing step shown in Step S50 in FIG. 7, polishing is separately performed on both faces one face after the other. Instead, in some cases, a single-sided polishing step is performed in which mirror polishing is performed on only a single face of the wafer. Such a single-sided polishing step (Step S55) also realizes extremely high flatness of the wafer after the process in the same way as in the double-sided polishing step. The steps other than Step S55 shown in FIG. 9 are the same as those other than Step S50 shown in FIG. 7. Accordingly, description thereof will be omitted.

Also, in some cases, as shown in FIG. 10, as a rough finishing step, after the lapping step (Step S24), double-sided grinding (Step S26) is performed in which finishing grinding is separately performed on both faces of the wafer one face after the other, following which etching is performed on one face of the wafer (Step S45). In the etching step, surface treatment (etching) is performed on the wafer using a chemical corrosion method.

It should be noted that, as a method for manufacturing a mirror surface wafer obtained by mirror-polishing one face or both faces of a wafer, a technique has been proposed in which, before a finishing mirror polishing step, high-precision grinding is performed on at least one face or both faces of the wafer (see Japanese Examined Patent Application Publication No. H6-61681, for example).

Conventionally, even large-diameter wafers have a diameter of 300 mm or less and a thickness of around 800 μm, for example. For such wafers having a conventional size, after the double-sided simultaneous grinding step (S20 in FIG. 7 and FIG. 9) performed as a rough-finishing step, or after the lapping step (Step S24 in FIG. 8 and FIG. 10) performed as a rough-finishing step, a finishing step is separately performed on both faces thereof one face after the other. In this case, the wafer has sufficient rigidity such that the effect of residual mechanical stress generated in the previous steps is small. Thus, there is no particular problem.

However, in recent years, there are more wafers with greater diameter. In a case in which the conventional manufacturing process is applied with no modification to manufacturing of wafers having a diameter of 450 mm or more and a thickness of around 800 to 1300 μm or less, for example, such a manufacturing process leads to the following problem.

That is to say, in a case in which single-sided finishing such as the aforementioned double-sided grinding, single-sided polishing, single-sided etching, etc., has been performed without removing residual mechanical stress 1a due to processing on both faces of a wafer 1 as shown in FIG. 11, deformation (warpage) of the wafer 1 increases as the residual mechanical stress 1a is removed in the finishing step as shown in FIG. 12. Such deformation leads to a problem in that the state in which the wafer is held cannot be maintained during single-sided finishing, leading to a high probability that the process will fail, an example of which includes a situation in which the wafer is dislodged or falls out, and accordingly, predetermined processing cannot be performed, leading to cracking of the wafer. The reason is thought to be that the thickness of the wafer becomes relatively small as the diameter of the wafer is increased, leading to reduced rigidity.

As described above, in recent years, there has been demand for a method for manufacturing a semiconductor wafer in which residual mechanical stress generated during processing is removed so as to suppress deformation or cracking of the wafer, thereby providing stable semiconductor wafer manufacturing even if the wafers have a large diameter.

### SUMMARY OF THE INVENTION

The present invention has been made in view of the aforementioned situation. It is an object of the present invention to provide a method for manufacturing a semiconductor wafer in which, by removing residual mechanical stress generated during processing, deformation and cracking of the wafer is suppressed, thereby providing a stable manufacturing method even if the wafer is a large-diameter wafer.

In a first aspect of the present invention, in order to achieve the aforementioned object, a method for manufacturing a semiconductor wafer is provided, the method including: a slicing step for slicing a semiconductor ingot to obtain a wafer; a rough-finishing step for rough-finishing processing of a cut surface of the wafer; a chamfering step for chamfering an edge portion of the wafer; a double-sided simultaneous processing step for simultaneously processing both faces of the wafer in order to remove residual mechanical stress generated on both faces of the wafer due to the slicing step and the rough finishing step; a single-sided finishing step for separately performing finishing processing on at least one face of the wafer; and a cleaning step for cleaning the wafer.

According to the first aspect of the invention, the double-sided simultaneous processing step is implemented before the single-sided finishing step. Thus, residual mechanical stress generated to both faces of the wafer due to the slicing step and the rough finishing step can be removed before the single sided finishing step is performed. Thus, deformation and cracking of the wafer is suppressed in the single-sided finishing step, even if the wafer is a large-diameter wafer. This provides a method for stably manufacturing semiconductor wafers.

In a second aspect of the invention described in the first aspect, the double-sided simultaneous processing step preferably includes a double-sided simultaneous polishing step for simultaneously polishing both faces of the wafer and a double-sided etching step for simultaneously etching both faces of the wafer. Furthermore, the single-sided finishing step preferably includes any one of a double-sided polishing step for separately polishing both faces of the wafer one face after the other, a single-sided polishing step for polishing only one face of the wafer, and a single-sided etching step for etching only one face of the wafer.

According to the second aspect of the invention, the double-sided etching step and the double-sided simultaneous polishing step are implemented before a single-sided finishing step which is any one of a double-sided polishing step, a single-sided polishing step, and a single-sided etching step. Thus, residual mechanical stress generated on both faces of the wafer due to the slicing step and the rough finishing step can be removed before the single sided finishing step is performed. Thus, deformation and cracking of the wafer is suppressed in the single-sided finishing step, even if the wafer is a large-diameter wafer. This provides a method for stably manufacturing semiconductor wafers.

In a third aspect of the invention described in either the first aspect or the second aspect, the wafer preferably has a diameter of 450 mm or more, and a thickness of 800 to 1300 μm.

According to the third aspect of the invention, wafers having an exceedingly large diameter, for which there has been a demand in recent years, can be manufactured with high yield.

The present invention provides a method for manufacturing a semiconductor wafer in which residual mechanical stress generated during processing is removed, thereby allowing semiconductor wafers to be stably manufactured even if the wafers have a large diameter.

### BRIEF DESCRIPTION OF THE DRAWINGS

FIG. 1 is a flowchart which shows a method for manufacturing a safer according to a first embodiment of the present invention;

FIG. 2 is a flowchart which shows a method for manufacturing a wafer according to a second embodiment of the present invention;

FIG. 3 is a flowchart which shows a method for manufacturing a wafer according to a third embodiment of the present invention;

FIG. 4 is a flowchart which shows a method for manufacturing a wafer according to a fourth embodiment of the present invention;

FIG. 5 is a flowchart which shows a method for manufacturing a wafer according to a fifth embodiment of the present invention;

FIG. 6 is a flowchart which shows a method for manufacturing a wafer according to a sixth embodiment of the present invention;

FIG. 7 is a flowchart which shows a conventional and general method for manufacturing a wafer;

FIG. 8 is a flowchart which shows a conventional and general method for manufacturing a wafer;

FIG. 9 is a flowchart which shows a conventional and general method for manufacturing a wafer;

FIG. 10 is a flowchart which shows a conventional and general method for manufacturing a wafer;

FIG. 11 is a schematic side view which shows a wafer having residual mechanical stress generated due to a slicing step and a rough finishing step; and

FIG. 12 is a schematic side view which shows a warped wafer.

### DETAILED DESCRIPTION OF THE INVENTION

Detailed description will be made below regarding embodiments of the present invention with reference to the drawings. It should be noted that the embodiments are by no means intended to restrict the present invention.

### First Embodiment

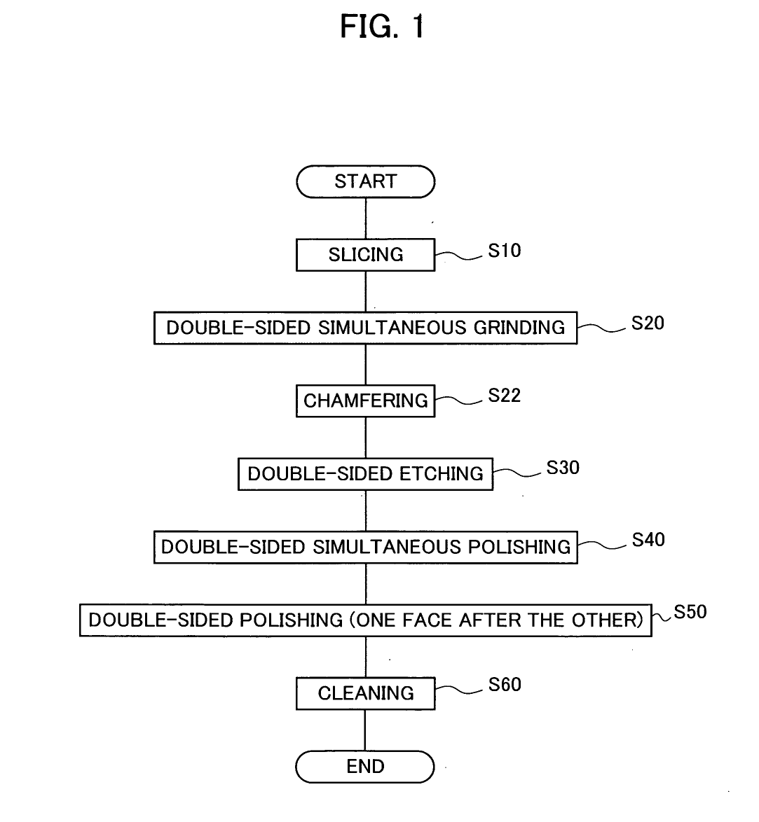

FIG. 1 is a flowchart which shows a method for manufacturing a wafer according to a first embodiment of the present invention. It should be noted that, in the following description, the same steps as those in the manufacturing process described above in the conventional technique are denoted by the same reference numerals, and description will be omitted or simplified.

Referring to FIG. 1, description will be made regarding a method for manufacturing a wafer according to the first embodiment. First, in a slicing step (Step S10), a semiconductor ingot is sliced into disc-shaped thin wafers using a wire saw.

It should be noted that, in slicing using a wire saw, slicing is performed using a piano wire having a predetermined diameter with a machining liquid including abrasive grains having a predetermined diameter being supplied. Thus, such an arrangement requires only a small cutting margin as compared with an arrangement employing a disc-shaped inner diameter blade. Furthermore, such an arrangement allows batch slicing to be performed, thereby manufacturing multiple wafers at the same time. This provides the advantage of allowing the slicing to be performed during a shorter period of time than that provided using a disc-shaped inner diameter blade. Furthermore, a method employing a wire saw has only a small mechanical limitation even in the case of slicing into large-diameter wafers. Accordingly, in the case of slicing into large-diameter wafers (having a diameter of 450 mm or more), in particular, a method using a wire saw is preferably employed.

The wafer thus sliced in the aforementioned slicing step (Step S10) has poor flatness and large surface roughness on both faces thereof, leading to waviness of the wafer. Accordingly, the waviness is removed from the wafer in the following double-sided simultaneous grinding (rough-finishing) step (Step S20).

That is to say, in Step S20, the double-sided simultaneous grinding is performed on both faces of the wafer with grindstones (not shown) arranged on the front-face side and the back-face side of the wafer. For example, the double-sided simultaneous grinding is performed using a double-sided grinder by grinding both faces of the wafer sandwiched between the grindstones that rotate in directions reverse to each other.

In the following chamfering step (Step S22), in order to protect the edge of the wafer from chipping, the edge portion is chamfered.

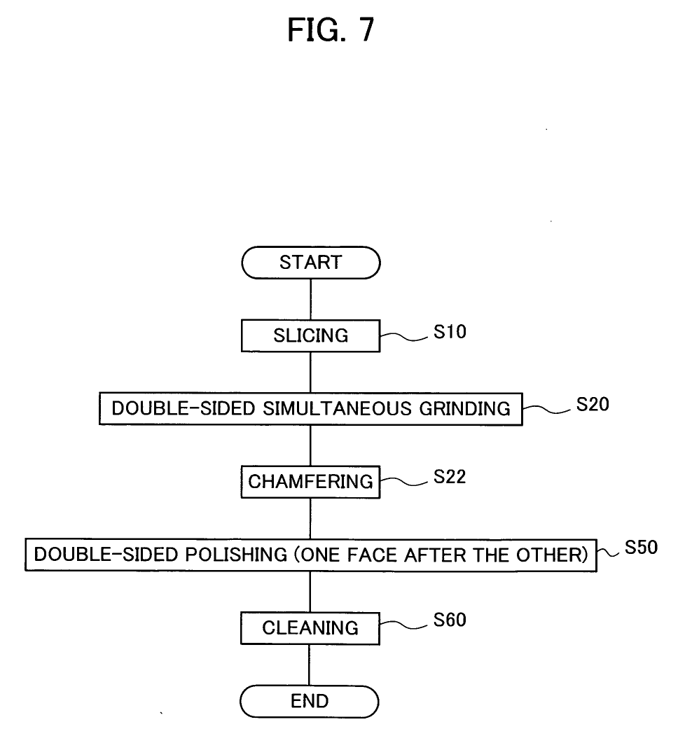

In the conventional technique (see FIG. 7), after the double-sided simultaneous grinding step (Step S20), the double-sided polishing (Step S50) is performed after the chamfering step (Step S22). With the present embodiment, before the double-sided polishing step (Step S50), a double-sided simultaneous processing step is implemented.

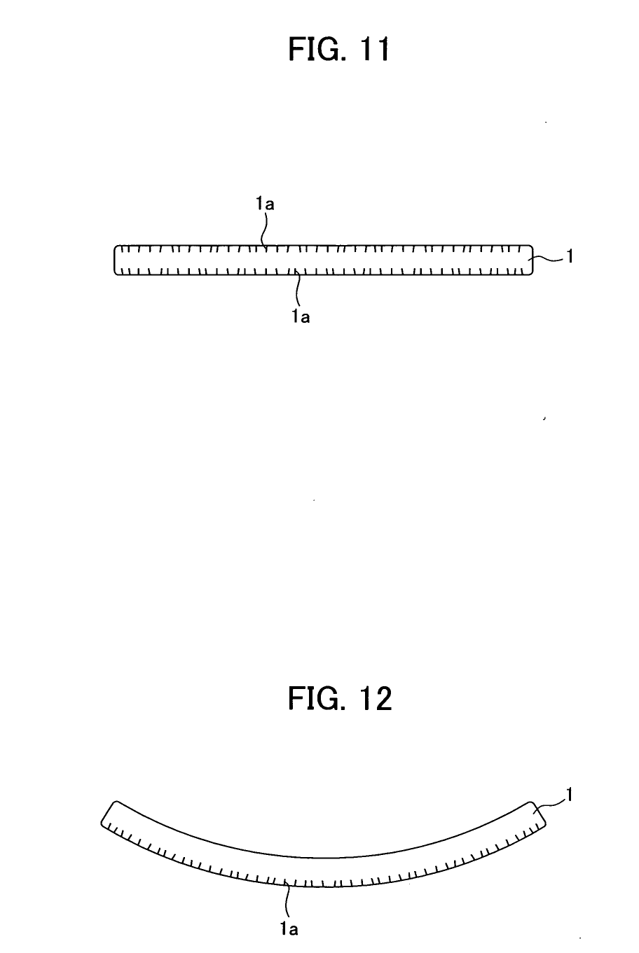

That is to say, in the double-sided simultaneous processing step, the both faces are processed at the same time so as to remove residual mechanical stress (see residual mechanical stress 1a shown in FIG. 11) generated due to the slicing step (Step S10) and the double-sided simultaneous grinding step (Step S20). The phrase “residual mechanical stress is removed” means that the residual mechanical stress is removed to a degree which ensures that the wafer will not be deformed (see FIG. 12) or cracked in the subsequent manufacturing steps.

As shown in FIG. 1, the double-sided simultaneous processing step is a step including a double-sided etching step (Step S30) for etching both faces of the wafer at the same time and a double-sided simultaneous polishing step (Step S40) for polishing both faces of the wafer at the same time.

The reason why the double-sided etching step (Step S30) is implemented is as follows. Residual mechanical stress (see residual mechanical stress 1a shown in FIG. 11) occurs due to the slicing step (Step S10 in FIG. 1), the double-sided simultaneous grinding step (Step S20), etc., as described above.

Such residual stress leads to contamination or impurities such as abrasive dust, silicon dust, etc. That is to say, the residual mechanical stress leads to adverse effects such as contamination or the like on the wafer manufacturing process, as well as leading to adverse effects such as degradation of the electronic properties of the device, malfunctioning of the device, etc.

Accordingly, with the present embodiment, the double-sided etching step (Step S30) is implemented principally in order to remove the residual mechanical stress and impurities on both face sides of the wafer. It should be noted that, in many cases, etching is performed using a mixed acid formed of HF (reducing agent) which is a strong acid, HNO₃ (oxidizing agent), and CH₃COOH (buffer agent), or using KOH, NaOH which are srtong srtong-alkaline.

Next, description will be made regarding the double-sided simultaneous polishing step (Step S40). The double-sided simultaneous polishing step is implemented using a double-sided polishing apparatus in order to improve the flatness of the wafer, as well as removing the residual mechanical stress that has been imparted to the wafer due to the previous steps (Step S10 and Step S20 in FIG. 1, etc.), for the same reason that the double-sided etching step (Step S30) is implemented.

With the double-sided polishing apparatus (not shown), one or several wafers thus subjected to the double-sided etching step (Step S30) are fixedly held at the same time via a carrier plate between a pair of platens that rotate in reverse directions, and both faces of each wafer are polished at the same time with abrasive grains being supplied.

As described above, by implementing the double-sided etching (Step S30) and the double-sided simultaneous polishing using the double-sided polishing apparatus (Step S40), such an arrangement improves the flatness of the wafer, as well as removing, at the same time, the residual mechanical stress that has been imparted to both face sides of the wafer due to the previous steps.

Thus, such an arrangement suppress deformation or cracking of the wafer, even if the double-sided polishing step (Step S50) is implemented as a downstream step, thereby providing stable manufacturing with high yield.

Lastly, in a cleaning step (Step S60), cleaning is performed so as to remove residual abrasive grains, impurities, etc., due to the previous steps. Thus, large-diameter wafers having desired specifications can be obtained.

As described above, with the method for manufacturing a semiconductor wafer according to the first embodiment, the residual mechanical stress generated during the process is removed, thereby suppressing deformation or cracking of the wafer, even if the wafer is a large-diameter wafer (e.g., wafer having a diameter of 450 mm or more and a thickness of around 800 to 1300 μm or less). This provides a stable manufacturing method.

### Second Embodiment

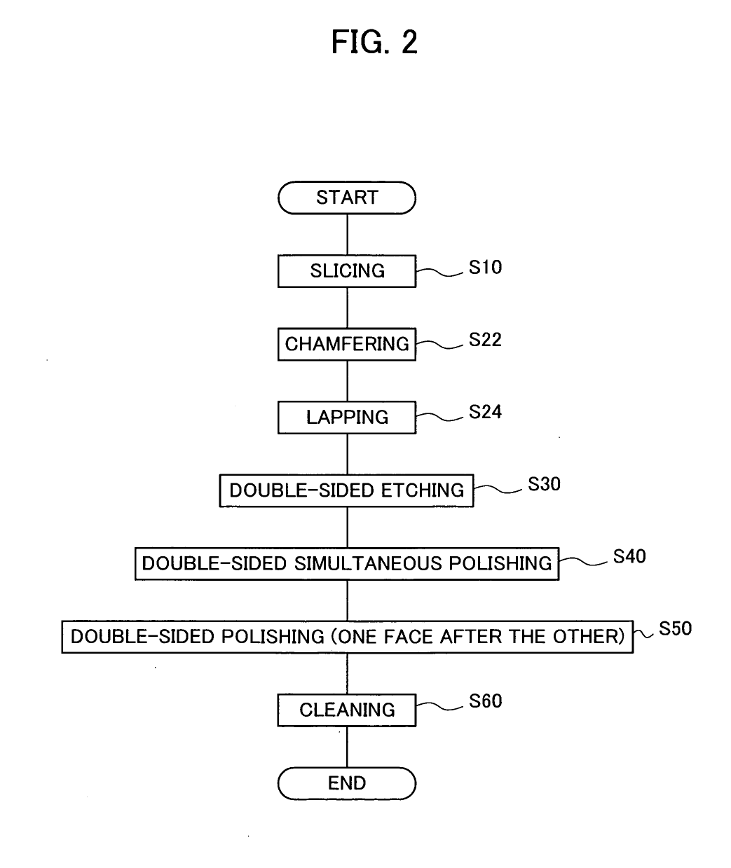

FIG. 2 is a flowchart which shows a method for manufacturing a wafer according to a second embodiment of the present invention. As shown in S24 in FIG. 2, in the second embodiment, a lapping step (rough-finishing step) is implemented, instead of the double-sided simultaneous grinding in Step S20 shown in FIG. 1 in the above-described first embodiment.

In the lapping step (Step S24), the wafer is planed so as to improve the flatness by removing the waviness of the wafer that has occurred in the slicing step (Step S10). It should be noted that the steps other than Step S24 shown in FIG. 2 are the same as those other than Step S20 shown in FIG. 1 in the above-described first embodiment. Furthermore, the second embodiment provides the same advantages as those of the above-described first embodiment. Accordingly, description thereof will be omitted.

As described above, the method for manufacturing a semiconductor wafer according to the second embodiment provides the same advantages as those of the above-described first embodiment.

### Third Embodiment

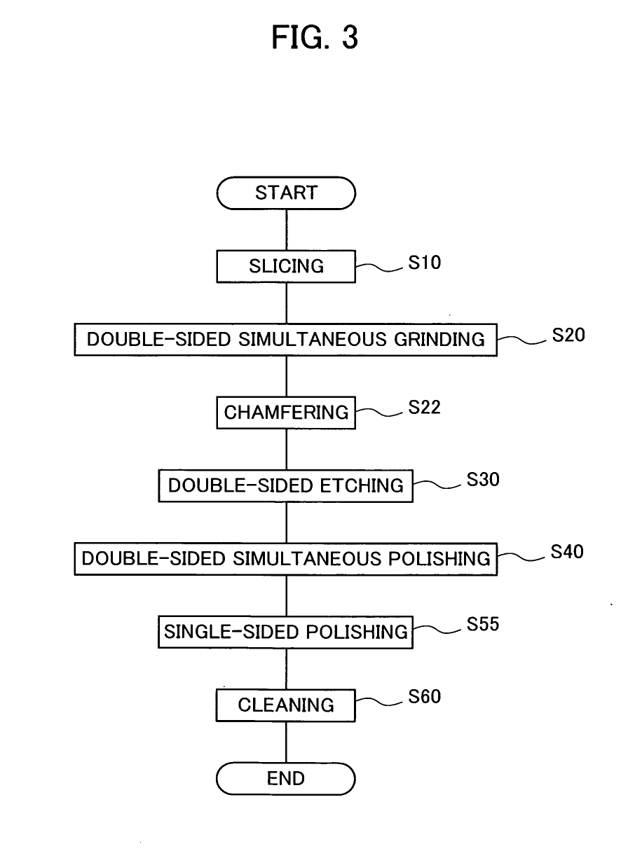

FIG. 3 is a flowchart which shows a method for manufacturing a wafer according to a third embodiment of the present invention. As shown in Step S55 in FIG. 3, in the third embodiment, a single-sided polishing step (single-sided finishing step) for mirror-polishing one face of a wafer is implemented, instead of the double-sided polishing in Step S50 shown in FIG. 1 in the above-described first embodiment.

Such a single-sided polishing step (Step S55) also provides extremely high flatness of the wafer in the same way as with the double-sided polishing step in Step S50 shown in FIG. 1. It should be noted that the steps other than Step S55 shown in FIG. 3 are the same as those other than Step S50 shown in FIG. 1 in the above-described first embodiment. Furthermore, the third embodiment provides approximately the same advantages. Accordingly, description thereof will be omitted.

As described above, the method for manufacturing a semiconductor wafer according to the third embodiment provides the same advantages as those of above-described first embodiment.

### Fourth Embodiment

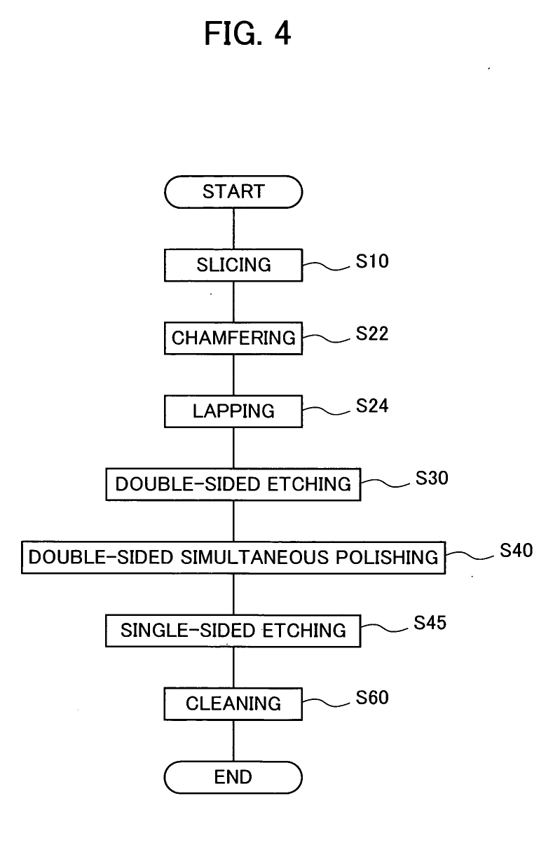

FIG. 4 is a flowchart which shows a method for manufacturing a wafer according to a fourth embodiment of the present invention. As shown in Step S45 in FIG. 4, the fourth embodiment differs from the above-described second embodiment in that a single-sided etching step is implemented instead of the double-sided polishing step (Step S50) shown in FIG. 2 in the above-described second embodiment.

Also, with the fourth embodiment, by implementing the double-sided etching (Step S30) and the double-sided simultaneous polishing (Step S40) before the single-sided etching step (Step S45), such an arrangement removes the residual mechanical stress that has been imparted to the wafer due to the previous steps such as the slicing step (Step S10), the lapping step (Step S24), etc.

Thus, with the method for manufacturing a semiconductor wafer according to the fourth embodiment, deformation or cracking of the wafer is suppressed, even if the single-sided etching step (Step S45) is implemented as a downstream step. Thus, such an arrangement provides stable manufacturing.

### Fifth Embodiment

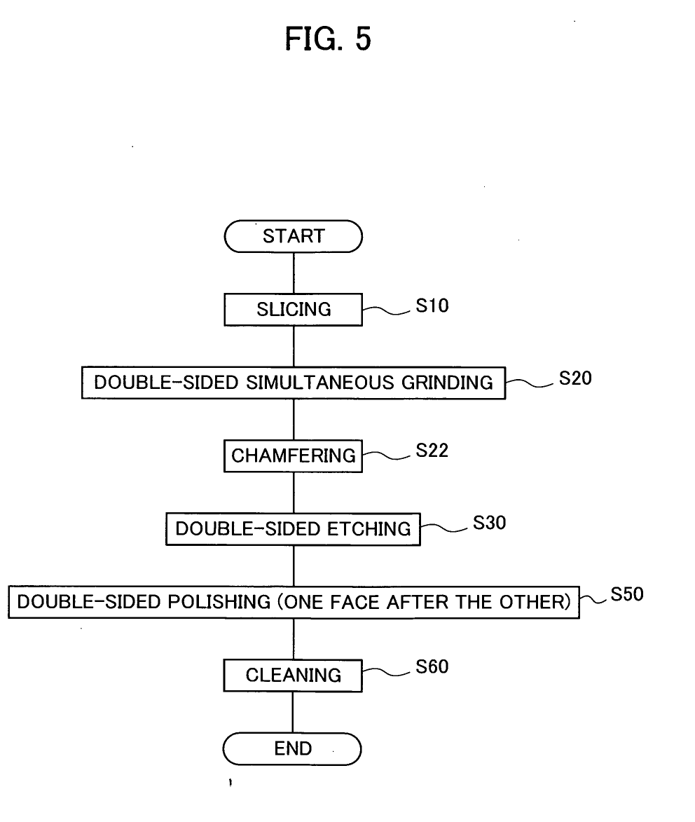

FIG. 5 is a flowchart which shows a method for manufacturing a wafer according to a fifth embodiment of the present invention. The fifth embodiment differs from the above-described first embodiment in that the double-sided simultaneous polishing step (Step S40) shown in FIG. 1 in the above-described first embodiment is excluded. Furthermore, the fifth embodiment differs from the manufacturing method shown in FIG. 7 in the above-described conventional technique in that the double-sided etching step (Step S30) is added between the chamfering step (Step S22) and the double-sided polishing step (Step S50).

By adding the double-sided etching step (Step S30) to the conventional manufacturing process (see FIG. 7), such an arrangement is capable of removing the residual mechanical stress that has been imparted to the wafer due to the previous steps such as the double-sided simultaneous grinding step (Step S20), etc.

Thus, with the method for manufacturing a semiconductor wafer according to the fifth embodiment, deformation and cracking of the wafer is suppressed, even if polishing is separately performed on both faces thereof one face after the other in the following double-sided polishing step (Step S50). Thus, such an arrangement provides a stable manufacturing method.

### Sixth Embodiment

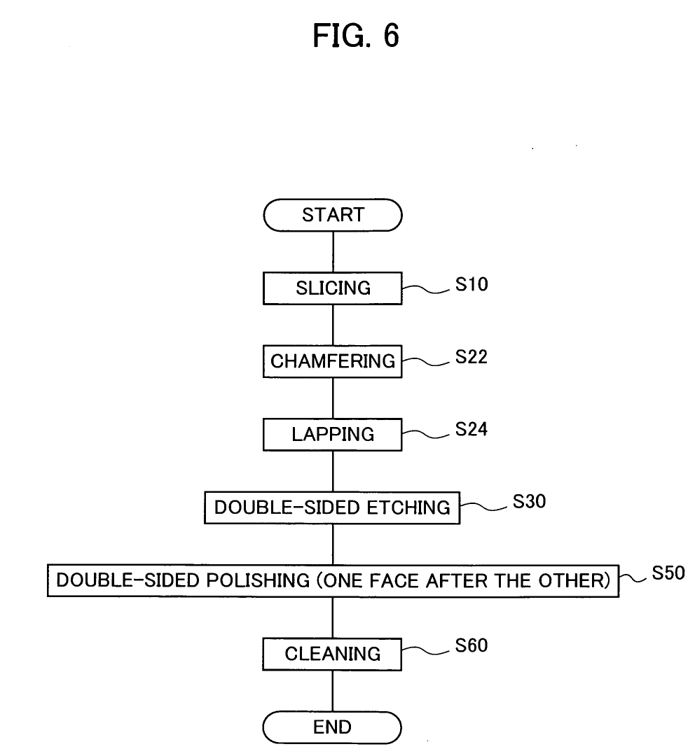

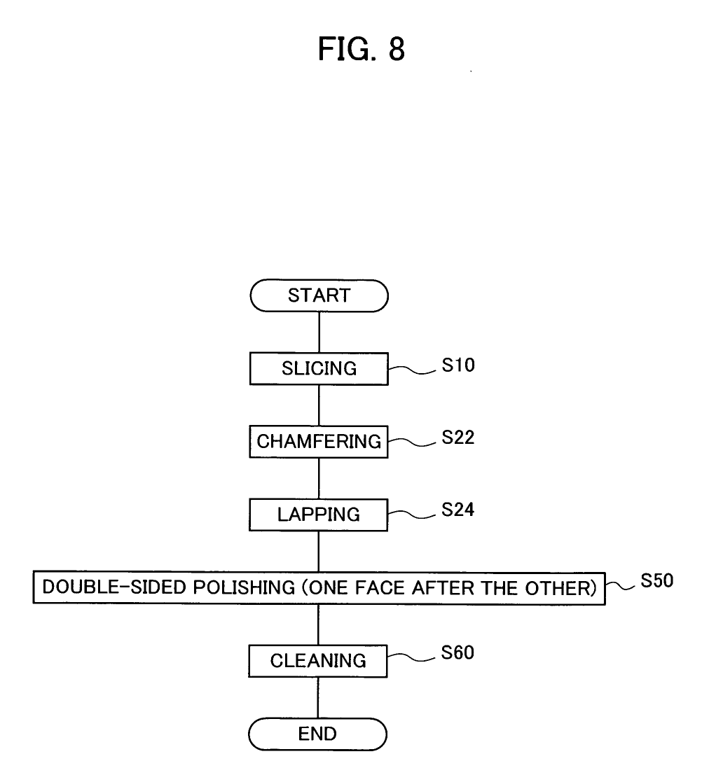

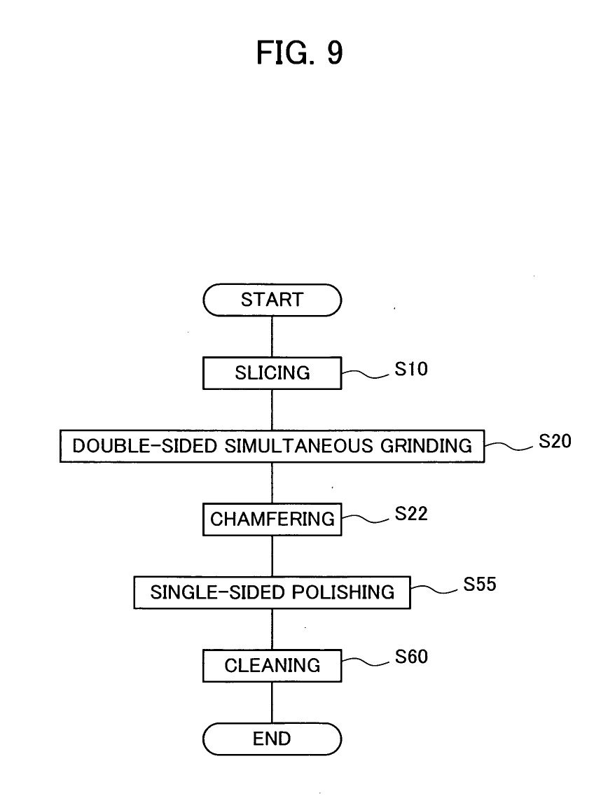

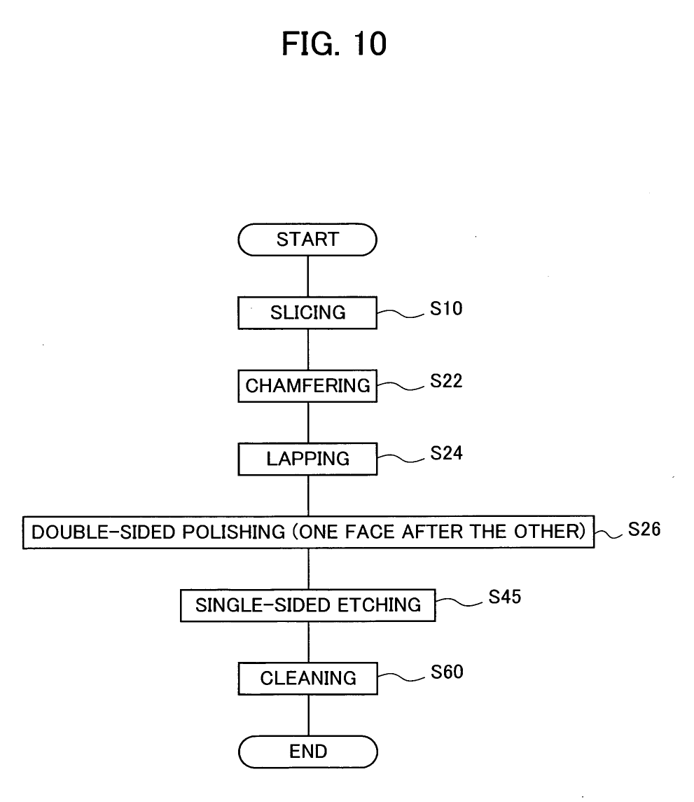

FIG. 6 is a flowchart which shows a method for manufacturing a wafer according to a sixth embodiment of the present invention. The sixth embodiment differs from the above-described second embodiment in that the double-sided simultaneous polishing step (Step S40) shown in FIG. 2 in the above-described second embodiment is excluded. Furthermore, the sixth embodiment differs from the manufacturing method shown in FIG. 8 in the above-described conventional technique in that the double-sided etching step (Step S30) is added between the lapping step (Step S24) and the double-sided polishing step (Step S50).

By adding the double-sided etching step (Step S30) to the conventional manufacturing process (see FIG. 8), such an arrangement is capable of removing the residual mechanical stress that has been imparted to the wafer due to the previous steps such as the slicing step (step S10), the lapping step (Step S24), etc.

Thus, with the method for manufacturing a semiconductor wafer according to the sixth embodiment, deformation and cracking of the wafer is suppressed, even if polishing is separately performed on both faces thereof one face after the other in the following double-sided polishing step (Step S50). Thus, such an arrangement provides a stable manufacturing method.

It should be noted that, in the first embodiment through the fourth embodiment, description has been made assuming that the double-sided simultaneous processing step is a step including the double-sided etching step (Step S30) and the double-sided simultaneous polishing step (Step S40) (see FIGS. from 1 to 4). Furthermore, description has been made in the fifth embodiment and the sixth embodiment assuming that the double-sided simultaneous processing step is a double-sided etching step (S30) (see FIG. 5 and FIG. 6). However, the present invention is not restricted to such an arrangement.

That is to say, the double-sided simultaneous processing step is implemented in order to suppress deformation and cracking of the wafer in a single-sided finishing step (e.g., the double-sided polishing in Step S50 shown in FIG. 1 and FIG. 2) which is to be executed as a downstream step. Accordingly, only the double-sided simultaneous polishing step (Step S40) may be implemented as the double-sided simultaneous processing step, providing the aforementioned purpose is fulfilled.

Furthermore, the figures showing the example steps in the above-described embodiments are schematic diagrams showing the method for manufacturing a wafer, and are by no means intended to exclude a generally-required step such as an unshown cleaning step, etc., to be implemented between these steps.

What is claimed is:

1. A method for manufacturing a semiconductor wafer, the method comprising:
a slicing step for slicing a semiconductor ingot to obtain a wafer;
a rough-finishing step for rough-finishing processing of a cut surface of the wafer;
a chamfering step for chamfering an edge portion of the wafer;
a double-sided simultaneous processing step for simultaneously processing both faces of the wafer in order to remove residual mechanical stress generated on both faces of the wafer due to the slicing step and the rough finishing step;
a single-sided finishing step for separately performing finishing processing on at least one face of the wafer; and
a cleaning step for cleaning the wafer.

2. The method for manufacturing the semiconductor wafer according to claim 1,
wherein the double-sided simultaneous processing step includes a double-sided simultaneous polishing step for simultaneously polishing both faces of the wafer and a double-sided etching step for simultaneously etching both faces of the wafer; and
wherein the single-sided finishing step includes any one of a double-sided polishing step for separately polishing both faces of the wafer one face after the other, a single-sided polishing step for polishing only one face of the wafer, and a single-sided etching step for etching only one face of the wafer.

3. The method for manufacturing the semiconductor wafer according to claim 1, wherein the wafer has a diameter of 450 mm or more, and a thickness of 800 to 1300 μm.

4. The method for manufacturing the semiconductor wafer according to claim 2, wherein the wafer has a diameter of 450 mm or more, and a thickness of 800 to 1300 μm.
